(19) United States
(12) Patent Application Publication
(10) Pub. No.: US 2016/0069938 A1
(43) Pub. Date: Mar. 10, 2016

(54) INPUT VOLTAGE DETECTION CIRCUIT WITH A PARAMETER SETTING FUNCTION APPLIED IN A POWER CONVERTER AND PARAMETER SETTING AND CIRCUIT PROTECTING METHOD THEREOF

(71) Applicant: Richtek Technology Corporation, Zhubei City (TW)

(72) Inventors: Hsin-Yi WU, Taipei City (TW); Chien-Fu TANG, Hsinchu City (TW); Isaac Y. CHEN, Jubei City, Hsinchu County (TW)

(21) Appl. No.: 14/822,382

(22) Filed: Aug. 10, 2015

(30) Foreign Application Priority Data
Sep. 5, 2014 (TW) 103130907

(51) Int. Cl. G01R 19/165; H02H 3/087; H02M 1/32

(52) U.S. Cl. CPC G01R 19/165; H02M 1/32; H02H 3/087

(57) ABSTRACT

A parameter setting and circuit protecting method applied in a power converter are disclosed. An input voltage of the power converter is detected to generate a first detecting signal related to the input voltage. The first detecting signal will be thence compared with a threshold so as to generate a protecting signal for protecting the power converter. When a parameter setting signal is triggered, a current is provided so as to make the first detecting signal to generate a variation, thereby setting a parameter in accordance with the variation.

### FIELD OF THE INVENTION

The present invention is related generally to an input voltage detection circuit applied in a power converter and, more particularly, to an input voltage detection circuit with a parameter setting function and a parameter setting and circuit protecting method.

### BACKGROUND OF THE INVENTION

In an AC power system, the many protection functions need the information of the input voltage, such as the brown-in/out protection function. FIG. 1 shows an AC power converter with a brown-in/out protection function. Wherein, a control IC 10 controls a switching of a power switch 12 that is serially coupled to a primary coil Lp of a transformer T1 so as to generate an output voltage Vo. In order to achieve the brown-in/out protection function, the control IC 10 needs a pin HV to acquire the information of an input voltage VAC. Generally, the AC power converter works normally when the input voltage VAC is over 90V. When the input voltage VAC is below 90V, the performance of the AC power converter will be unsatisfactory. In addition, when the input voltage VAC is below 90V for a long time, the employed power device may be burned down if the quality of the power device is poorer. A power device of good quality might solve aforementioned problem; however, such power device of good quality results in a higher bill of materials cost. The brown-in/out protection can not only control the performance issue caused by the low input voltage VAC, but also is conducive to employ the cheaper power device. Thus, the brown-in/out protection is necessary in the AC power converter.

In some applications, the AC power converter also needs a parameter setting function, such as a burst mode level setting or a frequency reduction point setting. FIG. 2 shows an AC power converter with the burst mode level setting function and the frequency reduction point setting function. In which, a control IC 14 controls the switching of the power switch 12 that is serially coupled to the primary coil Lp of the transformer T1 so as to generate the output voltage Vo. In this kind of AC power converter, the level of an entry point of the burst mode is set by adjusting a resistor Rss that is coupled to a pin BURST. Moreover, the frequency reduction point is set by adjusting a resistor Rcs_rc that is coupled to a pin CS. Namely, the burst mode level setting function and the frequency reduction point setting function need a pin respectively to achieve the parameter setting.

As shown by FIGS. 1 and 2, the protecting function and the parameter setting function of the AC power converter need a pin respectively. However, in the control IC of a low pin-count, for example the control IC with 6 pins, insufficient pins serve the protecting function and the parameter setting at the same time. Although the control IC with more pins can be utilized, the cost of such control IC is rather high. Herein, in order to reduce the using amount of the pins, some methods are proposed to achieve multiple functions with a single pin. For example, a U.S. patent publication no. 2013/0083562 discloses a method utilizing a single pin to achieve the brown-in/out protection function and the overheat protection function.

Therefore, it is desired a circuit and a method utilizing a single pin to achieve the protecting function and the parameter setting function.

### SUMMARY OF THE INVENTION

An object of the present invention is to provide an input voltage detection circuit with a parameter setting function applied in a power converter and a parameter setting and circuit protecting method thereof.

Another object of the present invention is to provide a circuit and a method utilizing a single pin in the power converter to protect circuits and set parameters.

According to the present invention, an input voltage detection circuit with a parameter setting function applied in a power converter comprises a first detecting circuit, a protecting circuit, a current source, and a second detecting circuit. The first detecting circuit detects an input voltage of the power converter to generate a first detecting signal related to the input voltage. The protecting circuit generates a protecting signal according to the first detecting signal so as to protect the power converter. In time of setting the parameter, the current source provides a current to make the first detecting signal to generate a variation. The second detecting circuit acquires the variation in order to set the parameter.

According to the present invention, a parameter setting and circuit protecting method of the power converter comprises detecting an input voltage of the power converter to generate the first detecting signal related to the input voltage. Thence, a protecting signal is generated according to the first detecting signal so as to protect the power converter. In time of setting the parameter, the method of the present invention provides a current to make the first detecting signal to generate a variation, and detects the variation to set the parameter.

Since the present invention utilizes the first detecting signal to protect circuits and set parameters, it only needs one single pin to receive the first detecting signal so as to achieve circuit protect function and parameter setting function.

### BRIEF DESCRIPTION OF THE DRAWINGS

These and other objectives, features and advantages of the present invention will become apparent to those skilled in the art upon consideration of the following description of the preferred embodiments according to the present invention taken in conjunction with the accompanying drawings, in which:

FIG. 1 is a conventional AC power converter with a brown-in/out protection function;

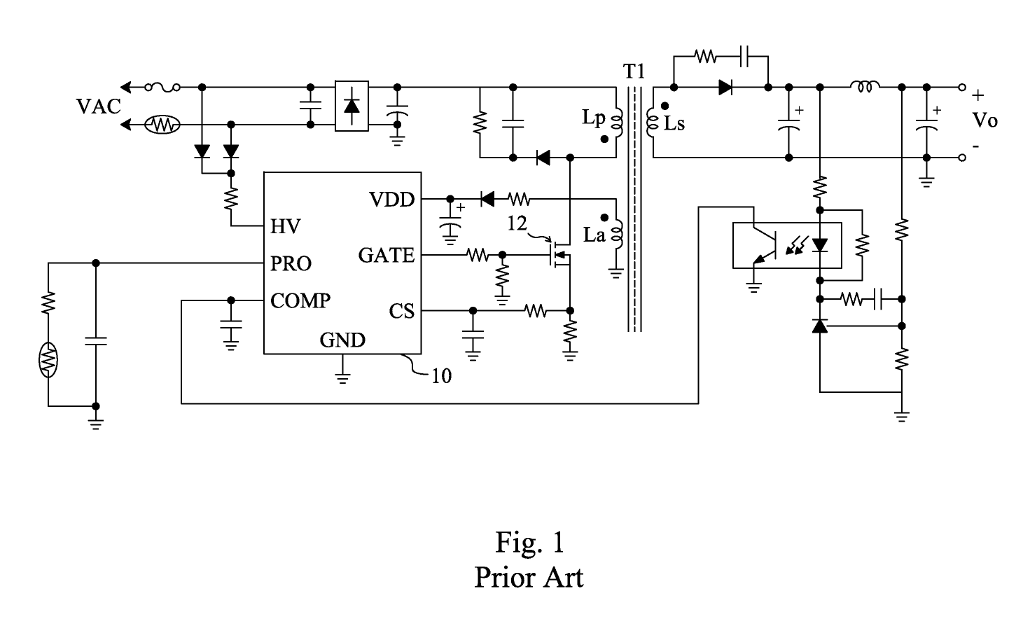

FIG. 2 is a conventional AC power converter with a burst mode level setting function and a frequency reduction point setting function;

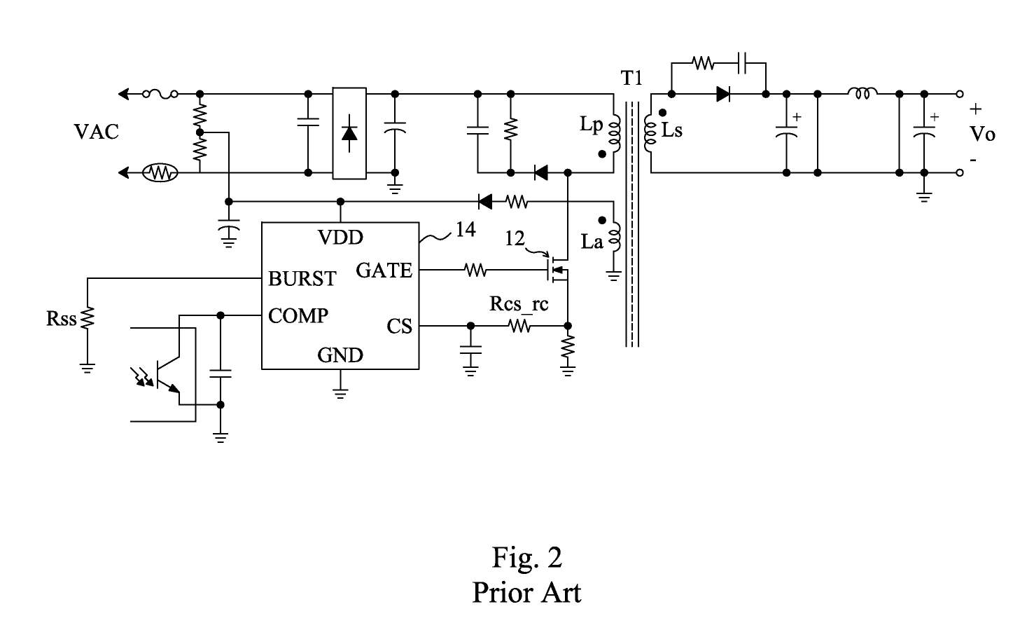

FIG. 3 is an AC power converter employing the present invention;

FIG. 4 is an embodiment of the present invention; and

FIG. 5 shows a waveform drawing for illustrate the operation of the circuit in FIG. 4.

### DETAILED DESCRIPTION OF THE INVENTION

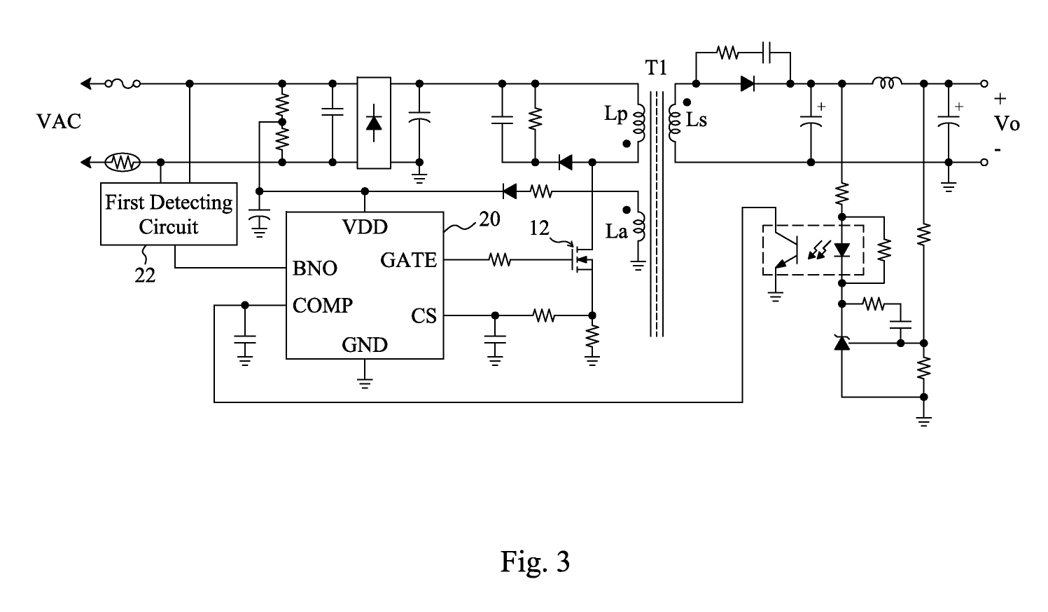

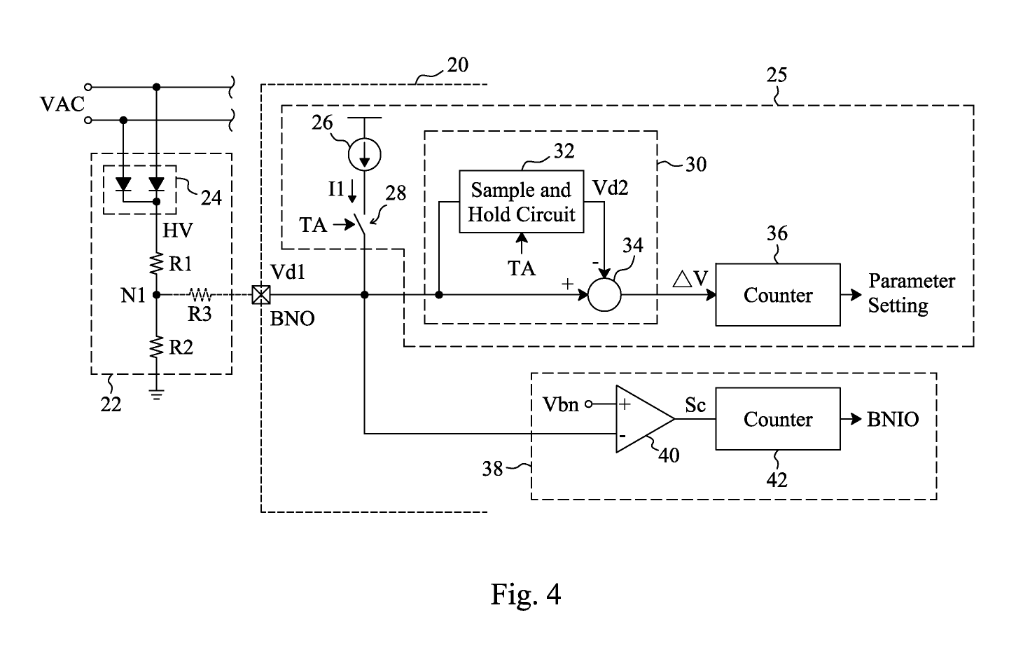

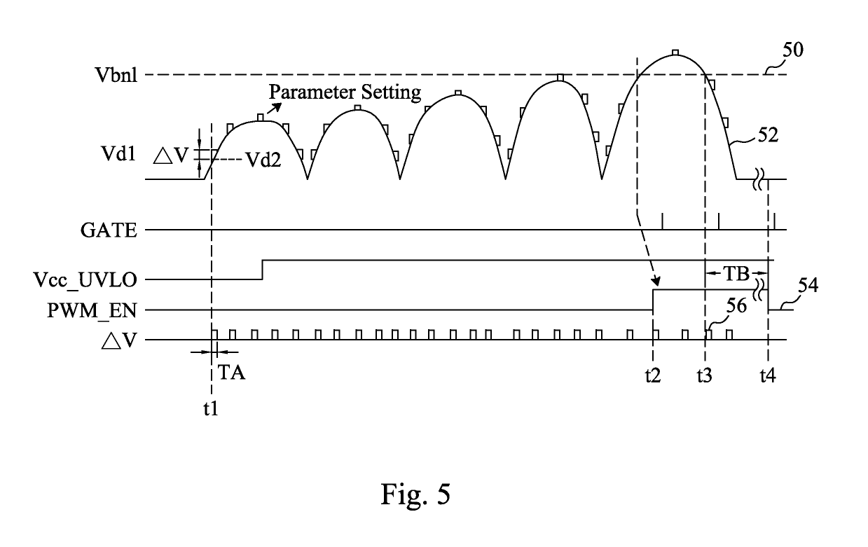

FIG. 3 shows an AC power converter employing the present invention. In which, a control IC 20 controls the switching of a power switch 12 that is serially coupled to a primary coil Lp of a transformer T1 so as to generate an output voltage Vo. This AC power converter utilizes a single pin BNO to achieve a circuit protecting function and a parameter setting function. FIG. 4 shows an embodiment of the present invention that comprises a first detecting circuit 22, a parameter setting circuit 25, and a protecting circuit 38. The parameter setting circuit 25 includes a current source 26, a switch 28, a second detecting circuit 30, and a counter 36. The first detecting circuit 22 and the protecting circuit 38 are utilized to provide a brown-in/out protection function. The first detecting circuit 22, the current source 26, the switch 28, the second circuit 30 and the counter 36 are utilized to achieve the parameter setting function. FIG. 5 shows a waveform drawing for illustrate the operation of the circuit in FIG. 4, in which comprises a waveform 50 of a threshold Vbn, a waveform 52 of a first detecting signal Vd1, a waveform 54 of an enabling signal PWM_EN, and a waveform 56 of a variation ΔV of the first detecting signal Vd1.

Referring to FIGS. 4 and 5, the first detecting circuit 22 detects an input voltage VAC to generate the first detecting signal Vd1 related to the input voltage VAC. The first detecting circuit 22 includes a rectifying circuit 24, a first resistor R1 and a second resistor R2. The rectifying circuit 24 rectifies the input voltage VAC to generate a rectified voltage HV. The first resistor R1 and the second resistor R2 are serially coupled between the rectifying circuit 24 and a ground for dividing the rectified voltage HV so as to generate the first detecting signal Vd1, as shown by the waveform 52 in FIG. 5, at a node N1 between the first resistor R1 and the second resistor R2. The protecting circuit 38 couples to the first detecting circuit 22 via the pin BNO and generates a protecting signal BNIO according to the first detecting signal Vd1 for protecting the AC power converter. The protecting circuit 38 includes a comparator 40 and a counter 42. The comparator 40 compares the first detecting signal Vd1 with a threshold Vbn. When the first detecting signal Vd1 is larger than the threshold Vbn, the comparator 40 ends a comparing signal Sc. Herein, the input voltage VAC is sufficient to support a normal work of the AC power converter. Accordingly, the enabling signal PWM_EN is triggered so as to start up the AC power converter as shown by the waveforms 50, 52, 54 and time t2. When the first detecting signal Vd1 is lower than the threshold Vbn, the comparator 40 generates the comparing signal Sc, and the counter 42 counts a duration of the comparing signal Sc. While the duration of the comparing signal Sc reaches a preset time TB as shown by t3 to t4 in FIG. 5, it means that the input voltage VAC is too low to support the normal work of the AC power converter. Accordingly, the counter 42 generates the protecting signal BNIO so as to end the enabling signal PWM_EN, thereby turning off the AC power converter and achieving the brown-in/out protection. The present invention is not limited in the brown-in/out protection in this preferred embodiment. Other circuit protection functions with an input voltage information are also included in the inventive spirit of the present invention.

In time of setting parameters, a parameter setting signal TA is triggered to turn on the switch 28. Accordingly, the current I1 of the current source 26 flows through the second resistor R2 via the switch 28 and the pin BNO. At the same time, the first detecting signal Vd1 generates a variation ΔV=I1×R2. The second detecting circuit 30 includes a sample and hold circuit 32 and a subtractor 34. While the parameter setting signal TA is triggered, the sample and hold circuit 32 samples and holds the first detecting signal Vd1 so as to generate a second detecting signal Vd2 as shown by time t1 and the waveform 52 in FIG. 5. The subtractor 34 subtracts the second detecting signal Vd2 from the first detecting signal Vd1 so as to acquire the variation ΔV. The counter 36 counts the variation ΔV and sets the parameter in accordance with the variation ΔV, thereby achieving the parameter setting function. Take the frequency reduction point setting function as an example. When the variation ΔV is 0.1V, the frequency reduction point is set 2.35V. When the variation ΔV is 0.2V, the frequency reduction point is set 2.25V. In the present invention, a pulse width of the parameter setting signal TA is quite short (about 100 μs). Thus, the operation of the protecting circuit 38 will not be influenced. In the circuit of FIG. 4, the first resistor R1 and the second resistor R2 determine a voltage dividing ratio. Thus, a resistance of the second resistor R2 is not easy to be varied for setting parameters. Accordingly, a third resistor R3 is set between the node N1 and an output terminal (the pin BNO) of the first detecting circuit 22 for determining the variation ΔV=I1×(R2+R3). Wherein, the third resistor can be a variable resistor. Hereby, a resistance of the third resistor R3 can be adjusted from the external part of the control IC 20, and the variation ΔV can be controlled. Therefore, the parameter for setting can be controlled. It should be noted that controlling the current I1 of the current source 26 can also readily adjust the variation ΔV.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

1-17. (canceled)

18. An input voltage detection circuit with a parameter setting function applied in a power converter comprising:
a first detecting circuit for detecting an input voltage of the power converter to generate a first detecting signal related to the input voltage;
a protecting circuit connected to the first detecting circuit for generating a protecting signal according to the first detecting signal for protecting the power converter; and
a parameter setting circuit connected to the first detecting circuit for setting a parameter according to the first detecting signal.

19. The input voltage detection circuit of claim 18, wherein the parameter setting circuit comprises:
a current source connected to the first detecting circuit for providing a current when a parameter setting signal is triggered so as to make the first detecting signal to generate a variation; and
a second detecting circuit connected to the first detecting circuit for acquiring the variation for setting the parameter when the parameter setting signal is triggered.

20. The input voltage detection circuit of claim 19, further comprising a counter connected to the second detecting circuit for counting the variation provided by the second detecting circuit so as to set the parameter.

21. The input voltage detection circuit of claim 18, wherein the protecting signal triggers a brown-in/out protection.

22. The input voltage detection circuit of claim 18, wherein the protecting circuit turns off the power converter when the first detecting signal is lower than a threshold for a preset time.

23. The input voltage detection circuit of claim 18, wherein the first detecting circuit comprises:
a rectifying circuit connected to an input of the power converter for rectifying the input voltage so as to generate a rectified voltage;
a first resistor connected between the rectifying circuit and a node; and
a second resistor connected between the node and a ground;
wherein, the first resistor and the second resistor divide the rectified voltage so as to generate the first detecting signal at the node.

24. The input voltage detection circuit of claim 23, wherein the first detecting circuit further comprises a third resistor connected between the node and an output of the first detecting circuit for determining the variation.

25. The input voltage detection circuit of claim 18, wherein the protecting circuit comprises:
a comparator connected to the first detecting circuit for generating a comparing signal when the first detecting signal is lower than a threshold; and
a counter connected to the comparator for generating the protecting signal when a duration of the comparing signal reaches a preset time so as to turn off the power converter.

26. The input voltage detection circuit of claim 19, further comprising a switch connected between the current source and the first detecting circuit and turned on when the parameter setting signal is triggered, so that the first detecting signal generates the variation in accordance with the current of the current source.

27. The input voltage detection circuit of claim 19, wherein the second detecting circuit comprises:
a sample and hold circuit connected to the first detecting circuit for sampling and holding the first detecting signal when the parameter setting signal is triggered so as to generate a second detecting signal; and
a subtractor connected to the sample and hold circuit and the first detecting circuit for subtracting the second detecting signal from the first detecting signal so as to result the variation.

28. A parameter setting circuit protecting method of a power converter comprising the steps of
A. detecting an input voltage of the power converter so as to generate a first detecting signal related to the input voltage;
B. generating a protecting signal according to the first detecting signal so as to protect the power converter; and
C. setting a parameter according to the first detecting signal.

29. The parameter setting circuit protecting method of claim 28, wherein the step C comprises:
C1. providing a current when a parameter setting signal is triggered so as to make the first detecting signal to generate a variation; and
C2. detecting the variation when the parameter setting signal is triggered so as to set the parameter.

30. The parameter setting circuit protecting method of claim 29, wherein the step C2 comprises counting the variation so as to set the parameter.

31. The parameter setting circuit protecting method of claim 28, wherein the step B comprises generating the protecting signal so as to trigger a brown-in/out protection.

32. The parameter setting circuit protecting method of claim 28, wherein the step B comprises turning off the power converter when the first detecting signal is lower than a threshold for a preset time.

33. The parameter setting circuit protecting method of claim 28, wherein the step A comprises the steps of:
rectifying the input voltage to generate a rectified voltage; and
dividing the rectified voltage to generate the first detecting signal.

34. The parameter setting circuit protecting method of claim 29, further comprising controlling the variation so as to adjust the parameter.

35. The parameter setting circuit protecting method of claim 28, wherein the step B comprises:
generating a comparing signal when the first detecting signal is lower than a threshold; and
generating the protecting signal when a duration of the comparing signal achieves a preset time.

36. The parameter setting circuit protecting method of claim 29, wherein the step C2 comprises:
sampling and holding the first detecting signal when the parameter setting signal is triggered so as to generate a second detecting signal; and
subtracting the second detecting signal from the first detecting signal so as to result the variation.
